(19) United States
(12) Patent Application Publication
(10) Pub. No.: US 2026/0184176 A1
(43) Pub. Date: Jul. 2, 2026

(54) BATTERY EARLY WARNING METHOD AND APPARATUS, AND VEHICLE AND STORAGE MEDIUM

(71) Applicant: GREAT WALL MOTOR COMPANY LIMITED, Baoding (CN)

(72) Inventors: Wenrong KANG, Baoding (CN); Jiaxin HE, Baoding (CN)

(73) Assignee: GREAT WALL MOTOR COMPANY LIMITED, Baoding (CN)

(21) Appl. No.: 18/866,079

(22) PCT Filed: May 4, 2023
(86) PCT No.: PCT/CN2023/092095

§ 371 Date: Nov. 15, 2024

(30) Foreign Application Priority Data
May 16, 2022 (CN) 202210529442.X

(51) Int. Cl. B60L 3/00; G01R 31/367; G01R 31/382; G01R 31/392; G01R 31/396

(52) U.S. Cl. CPC B60L 3/0046; G01R 31/367; G01R 31/382; G01R 31/392; G01R 31/396; B60L 2240/545

(57) ABSTRACT

A battery early warning method includes: acquiring a reference ampere-hour integral value, wherein the reference ampere-hour integral value is an ampere-hour integral value when a battery is capable to be normally used at the current moment after the state of charge of the battery is lower than a preset state of charge threshold value; calculating an accumulated ampere-hour discharge capacity from the moment when the state of charge of the battery starts to be lower than the preset state of charge threshold value to the current moment; and when an accumulated ampere-hour discharge capacity value reaches the reference ampere-hour integral value, providing an early warning to prevent an over discharge of the battery.

### CROSS-REFERENCE TO THE RELATED APPLICATIONS

This application is the national phase entry of International Application No. PCT/CN2023/092095, filed on May 4, 2023, which is based upon and claims priority to Chinese Patent Application No. 202210529442.X, filed on May 16, 2022, the entire contents of which are incorporated herein by reference.

### TECHNICAL FIELD

The present disclosure relates to the technical field of batteries, and in particular to a battery early warning method, a battery early warning apparatus, a vehicle and a computer storage medium.

### BACKGROUND

At present, batteries are widely used in electric vehicles and energy storage, and due to the particularity, batteries are classified as dangerous goods. Therefore, how to protect the battery is the current technical problem to be solved.

In the prior art, a method for protecting the battery basically uses a battery SOC (State of Charge) to perform determination, and then performs battery early warning protection. In the prior art, when performing fault filtering of a battery SOC being too low, constant-time filtering is often used, and when the battery SOC is lower than a set SOC threshold value, the set time is continued to determine whether the battery SOC is too low.

The inventors of the present disclosure have found that there is still a technical problem in the prior art: whether the battery SOC is too low is only determined according to a constant time, and if the current of other powered devices is large, the same filtering duration is still used, which may lead to excessive actual discharged power, thus seriously damaging the battery. Therefore, how to effectively protect the battery and prevent damage caused by over discharge is the problem that a person skilled in the art needs to solve.

### SUMMARY

In view of the foregoing contents, embodiments of the present disclosure are presented to provide a battery early warning method, a battery early warning apparatus, a vehicle and a computer-readable storage medium that overcome or at least partially solve the above-mentioned problems.

In order to solve the above-mentioned problem, embodiments of the present disclosure disclose a battery early warning method, the method including:
acquiring a reference ampere-hour integral value, wherein the reference ampere-hour integral value is an ampere-hour integral value when a battery is capable to be normally used after a state of charge of the battery is lower than a preset state of charge threshold value;
calculating an accumulated ampere-hour discharge capacity from a moment when the state of charge of the battery starts to be lower than the preset state of charge threshold value to a current moment; and
providing an early warning to prevent an over discharge of the battery when a value of the accumulated ampere-hour discharge capacity reaches the reference ampere-hour integral value.

Optionally, the acquiring the reference ampere-hour integral value includes:
acquiring an initial reference ampere-hour integral value and a current state of health of the battery; and calculating the reference ampere-hour integral value on the basis of the initial reference ampere-hour integral value and the current state of health.

Optionally, the initial reference ampere-hour integral value is determined through following steps:
sampling the state of charge and a state of temperature of the battery according to a preset period within a preset filtering duration after the state of charge of the battery is lower than the preset state of charge threshold value;
respectively calculating an ampere-hour value corresponding to each preset period according to the state of charge and the state of temperature sampled in each preset period; and
accumulating the ampere-hour value corresponding to each preset period to obtain the initial reference ampere-hour integral value.

Optionally, the respectively calculating the ampere-hour value corresponding to each preset period according to the state of charge and the state of temperature sampled in each preset period includes:
determining an internal resistance state of the battery at the current moment and a state of power of the battery at the current moment according to the state of charge and the state of temperature that are sampled;
determining a historical open circuit voltage value of an open circuit voltage of the battery at a historical moment corresponding to a previous preset period according to the state of charge that is sampled; and
respectively calculating the ampere-hour value corresponding to each preset period according to the state of power, the internal resistance state and the historical open circuit voltage value of each preset period.

Optionally, after providing an early warning to prevent the over discharge of the battery when the value of the accumulated ampere-hour discharge capacity reaches the reference ampere-hour integral value, the method further includes:
automatically shutting down a function that consumes the battery without affecting normal driving.

Optionally, after providing an early warning to prevent the over discharge of the battery when the value of the accumulated ampere-hour discharge capacity reaches the reference ampere-hour integral value, the method further includes:
automatically switching the battery used to power a vehicle to a backup battery of the vehicle, wherein the backup battery is a battery that can be normally used.

Optionally, the providing an early warning to prevent the over discharge of the battery according to the accumulated ampere-hour discharge capacity when an accumulated ampere-hour discharge capacity value reaches the reference ampere-hour integral value includes:
when the value of the accumulated ampere-hour discharge capacity reaches the reference ampere-hour integral value, pushing an early warning message in at least one of the manners including voice, text and short message.

Disclosed in an embodiment of the present disclosure is a battery early warning apparatus, including:
an acquisition module configured for acquiring a reference ampere-hour integral value, wherein the reference ampere-hour integral value is an ampere-hour integral value when a battery is capable to be normally used after a state of charge of a battery is lower than a preset state of charge threshold value;
a determination module configured for calculating an accumulated ampere-hour discharge capacity from a moment when the state of charge of the battery starts to be lower than the preset state of charge threshold value to a current moment; and
an early warning module configured for providing an early warning to prevent the over discharge of the battery when a value of the accumulated ampere-hour discharge capacity reaches the reference ampere-hour integral value.

Optionally, the acquisition module includes:
an acquisition sub-module configured for acquiring an initial reference ampere-hour integral value and a current state of health of the battery; and
a first calculation sub-module configured for calculating the reference ampere-hour integral value on the basis of the initial reference ampere-hour integral value and the current state of health.

Optionally, the device further includes:
a sampling module configured for sampling the state of charge and a state of temperature of the battery according to a preset period within a preset filtering duration after the state of charge of the battery is lower than the preset state of charge threshold value;
a calculation module configured for respectively calculating an ampere-hour value corresponding to each preset period according to the state of charge and the state of temperature sampled in each preset period; and
an accumulation module configured for accumulating the ampere-hour value corresponding to each preset period to obtain the initial reference ampere-hour integral value.

Optionally, the calculation module includes:
a first determination sub-module configured for determining an internal resistance state of the battery at the current moment and a state of power of the battery at the current moment according to the state of charge and the state of temperature that are sampled;
a second determination sub-module configured for determining a historical open circuit voltage value of an open circuit voltage of the battery at a historical moment corresponding to a previous preset period according to the sampled state of charge; and
a second calculation sub-module configured for respectively calculating the ampere-hour value corresponding to each preset period according to the state of power, the internal resistance state and the historical open circuit voltage value of each preset period.

Optionally, the apparatus further includes:
an automatic shutdown module configured for automatically shutting down a function that consumes the battery without affecting normal driving.

Optionally, the apparatus further includes:
an automatic switching module configured for automatically switching the battery used to power a vehicle to a backup battery of the vehicle, wherein the backup battery is a battery that can be normally used.

Optionally, the early warning module includes:
a pushing sub-module configured for, when the value of the accumulated ampere-hour discharge capacity reaches the reference ampere-hour integral value, pushing an early warning message in at least one of the manners including voice, text and short message.

The present disclosure further discloses a vehicle including a memory, a processor, and a computer program stored on the memory and executable on the processor, wherein when the processor performs the computer program, the steps of the battery early warning method as described above are implemented.

The present disclosure further discloses a computer-readable storage medium, wherein the computer-readable storage medium stores a computer program thereon, and the computer program, when executed by a processor, implements steps of the battery early warning method described above.

The present disclosure further discloses a computing and processing device, including
a memory in which a computer-readable code is stored; and
one or more processors, wherein when the computer-readable code is executed by the one or more processors, the computing and processing device performs the battery early warning method described above.

The present disclosure further discloses a computer program, comprising a computer-readable code that, when running on a computing and processing device, causes the computing and processing device to perform the battery early warning method described above.

Embodiments of the disclosure include the following advantages.

With respect to the prior art, the present disclosure does not use a set time to determine the electric quantity state of a battery, but determines whether the battery is over discharged according to the relationship between the accumulated ampere-hour discharge capacity of the battery and a pre-detected reference ampere-hour integral value; using the set time, only the time period during which the battery is discharged can be determined, and the actual total ampere-hour value within the set time cannot be accurately known. In the present disclosure, an accumulated ampere-hour discharge capacity from a moment when the battery discharges to the current moment can be accurately calculated, and then the accumulated ampere-hour discharge capacity is compared with a reference ampere-hour integral value for protecting the battery, so as to determine whether the battery is over discharged, and early warning is provided to the battery in a timely manner, thereby preventing the problem of the over discharge of the battery, preventing the battery from being damaged due to over discharge, and thus effectively protecting the battery.

### BRIEF DESCRIPTION OF THE DRAWINGS

FIG. 1 is a flow chart of steps of a battery early warning method according to an embodiment of the present disclosure;

FIG. 2 is a flow chart of a step of determining an initial reference ampere-hour integral value according to an embodiment of the present disclosure;

FIG. 3 is a structural block diagram of a battery early warning apparatus according to an embodiment of the present application;

FIG. 4 schematically shows a block diagram of a computing and processing device for performing the method according to the present disclosure; and

FIG. 5 schematically shows a storage unit for holding or carrying a program code implementing the method according to the present disclosure.

### DETAILED DESCRIPTION OF THE EMBODIMENTS

For the purpose, features, and advantages of the present disclosure, which can be more clearly understood, the following will provide further detailed explanations of the present disclosure in conjunction with the accompanying drawings and specific embodiments. Obviously, the described embodiments are a part of the embodiments of the present disclosure, not all of them. Based on the embodiments of the present disclosure, all other embodiments obtained by a person of ordinary skill in the art without inventive effort fall within the scope of the present disclosure.

In the prior art, determining a SOC of the battery through constant-time filtering cannot effectively prevent the battery from being damaged due to the over discharge of the battery. In order to solve the above-mentioned technical problem, the present disclosure provides a battery early warning method, and the core concept thereof is that: after the state of charge of the battery is lower than a preset state of charge threshold value, an early warning for preventing the over discharge of the battery is provided according to an accumulated ampere-hour discharge capacity value and a reference ampere-hour integral value of the battery.

FIG. 1 is a flow chart of steps of a battery early warning method according to an embodiment of the present disclosure, which may specifically include the following steps:

Step 101, acquiring a reference ampere-hour integral value, wherein the reference ampere-hour integral value is an ampere-hour integral value when a battery is capable to be normally used after the state of charge of a battery is lower than a preset state of charge threshold value.

In the embodiments of the present disclosure, when using a vehicle or a battery, a user firstly detects the state of charge of the vehicle or the battery. When the state of charge of the battery reaches a preset state of charge threshold value, a reference ampere-hour integral value when the battery can be normally used after the state of charge of the battery is lower than the preset state of charge threshold value is acquired; and the reference ampere-hour integral value is the amount of electricity which can be normally discharged after the state of charge of the battery is lower than the preset state of charge threshold value, namely, discharging this amount of electricity will not cause over discharge of the battery. The preset state of charge threshold value and the preset filtering duration are set according to the data provided by the battery cell manufacturer. The present disclosure does not define the specific value of the preset state of charge threshold value, for example, it can be 20%, 40%, 60%, 80% or 100%.

In one example, when the state of charge of the vehicle reaches the preset state of charge threshold value, an initial reference ampere-hour integral value and a current state of health of the battery are acquired first, and then the reference ampere-hour integral value is calculated according to the initial reference ampere-hour integral value and the current state of health.

The initial reference ampere-hour integral value of the battery is obtained by pre-detecting relevant parameters of the battery, and then processing and calculating the relevant parameters and relevant data according to the corresponding relationship between the relevant parameters and relevant data provided by the battery cell manufacturer, among them, the initial reference ampere-hour integral value is pre-detected and determined. And when the user uses the vehicle or the battery, the initial reference ampere-hour integral value has been pre-stored in relevant processing device of the vehicle and the battery. When the state of charge of the battery is lower than the preset state of charge threshold value, the reference ampere-hour integral value is determined according to the current state of health and the initial reference ampere-hour integral value of the battery, so as to ensure that the reference ampere-hour integral value is not affected by aging of the battery, wherein the state of health can be a percentage of a current actual capacity of the battery and a capacity of the battery when leaving the factory, and can be expressed as the aging degree of the battery. As the battery is used, the lower the actual capacity of the battery, the higher the degree of aging of the battery, and the lower the state of health of the battery.

In the embodiment of the present disclosure, the health status of the battery may be periodically detected according to a preset time period, and the health status of the battery may also be detected each time the user uses the vehicle or the battery, and the health status of the battery may also be detected when the state of charge of the battery reaches a preset state of charge threshold value when the user uses the vehicle or the battery, so as to acquire the current health status of the battery, and then the current state of health of the battery is calculated according to the current health status of the battery, and then the reference ampere-hour integral value is calculated using the corresponding relationship between the current state of health of the battery and the initial reference ampere-hour integral value. The health status of the battery may be the current actual capacity of the battery, wherein the state of health of the battery is a percentage of the current actual capacity of the battery to the capacity of the battery when leaving the factory. Generally, the current state of health, the initial reference ampere-hour integral value and the reference ampere-hour integral value are in a multiplication relationship, and the reference ampere-hour integral value is obtained by multiplying the current state of health by the initial reference ampere-hour integral value. The specific relationship of the current state of health, the initial reference ampere-hour integral value, and the reference ampere-hour integral value is not limited herein, and may be set and calculated according to specific situations. Thus, the reference ampere-hour integral value is guaranteed to be the current state, is not affected by the aging of the battery, and avoids affecting the actual reference ampere-hour integral value of the battery due to the aging of the battery.

In one example, the initial reference ampere-hour integral value is determined by the following manner:

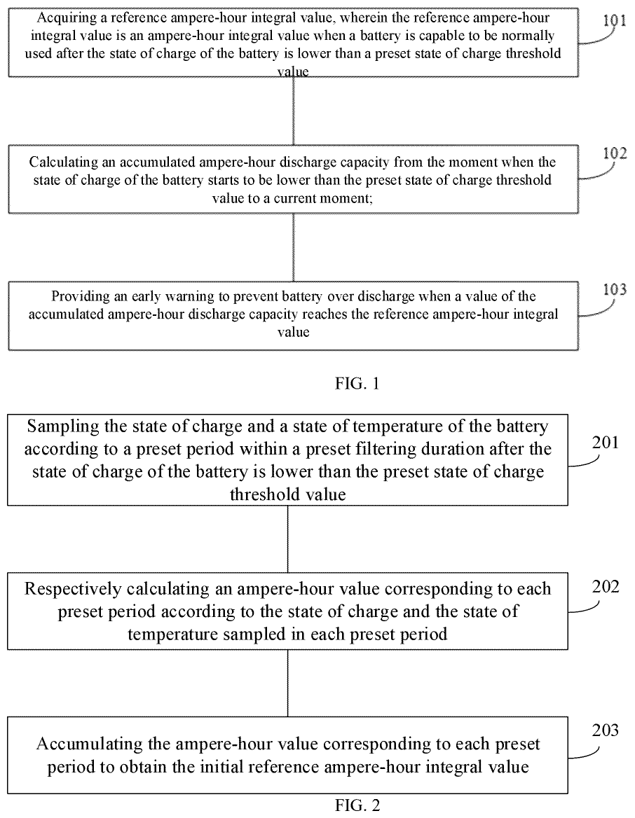

FIG. 2 is a flow chart of a step of determining an initial reference ampere-hour integral value according to an embodiment of the present disclosure, which is specifically provided as follows:

Step 201, sampling the state of charge and a state of temperature of the battery according to a preset period within a preset filtering duration after the state of charge of the battery is lower than the preset state of charge threshold value.

In this embodiment, the initial reference ampere-hour integral value of the battery may be determined when the battery has not left factory or has not been installed on the vehicle, or the initial reference ampere-hour integral value of the battery may be determined after the battery is installed on the vehicle, and the present disclosure is not limited thereto. The initial reference ampere-hour integral value may be different for different battery cell manufacturers of different models.

When the state of charge of the battery is lower than a preset state of charge threshold value, a first-order battery model can be used, and the first-order battery model can be implemented using an equivalent circuit of a single battery and Simscape language, and the state of charge and the state of temperature of the battery within a preset filtering duration are sampled according to a preset period, wherein the preset state of charge threshold value and the preset filtering duration are set according to data provided by a battery cell manufacturer. Data provided by different battery cell manufacturers can have differences; and the preset filtering duration is the duration during which the battery can be normally used after the state of charge of the battery is lower than the preset state of charge threshold value. For example, the preset battery state of charge threshold is 10%, the preset filtering duration is ten minutes, and the preset period is one second. When the state of charge of the battery reaches 10%, the time during which the battery can be normally used is ten minutes, and taking one second as a period, the state of charge and the state of temperature of the battery are sample every one second. The preset period can be determined according to a required finesse. The higher the calculated finesse is, the smaller the time of the preset period is. The time of the preset period is not particularly limited here.

Step 202, respectively calculating an ampere-hour value corresponding to each preset period according to the state of charge and the state of temperature sampled in each preset period.

After sampling the state of charge and the state of temperature of the battery according to the preset period, the state of charge and the state of temperature of each period are obtained, and then an ampere-hour value corresponding to each preset period is respectively calculated according to the state of charge and the state of temperature of each period, among them, the state of charge and the state of temperature of each period may be the same or may be different, and therefore the ampere-hour value corresponding to each preset period may also be the same state or may also be different states. For example, if the preset filtering duration is ten minutes and the preset period is one second, the state of charge and the state of temperature of the battery are sampled every one second, then the sampled state of charge and state of temperature will have six hundred groups of data, and then the ampere-hour values corresponding to the six hundred groups of preset periods are respectively calculated according to the sampled state of charge and state of temperature.

In one example, an internal resistance state of the battery at the current moment and a state of power of the battery at the current moment are determined according to the state of charge and the state of temperature that are sampled. The battery is sampled according to the preset period to obtain the state of charge of the battery at the current moment and the state of temperature of the battery at the current moment, and according to the corresponding relationship among the state of charge at the current moment, the state of temperature at the current moment, and the internal resistance state at the current moment, and the corresponding relationship among the state of charge at the current moment, the state of temperature at the current moment, and the state of power of the battery at the current moment, the internal resistance state of the battery at the current moment and the state of power of the battery at the current moment can be determined. The corresponding relationship among the current state of charge at the current moment, the state of temperature at the current moment, and the internal resistance state at the current moment and the corresponding relationship among the current state of charge at the current moment, the state of temperature at the current moment, and the state of power of the battery at the current moment are provided by the battery cell manufacturer according to batteries of different specifications. For example, the battery cell manufacturer provides the corresponding relationship among the state of charge at the current moment, the state of temperature at the current moment, and the internal resistance state at the current moment as shown in the following table (1), and the corresponding relationship among the state of charge at the current moment, the state of temperature at the current moment, and the state of power of the battery at the current moment as shown in the following table (2):

TABLE (1)

| | 5% | 10% | 15% | 20% |
|---|---|---|---|---|
| 10° C. | 1.115 KΩ | 1.040 KΩ | 0.983 KΩ | 0.966 KΩ |
| 25° C. | 0.639 KΩ | 0.615 KΩ | 0.604 KΩ | 0.575 KΩ |

TABLE (2)

| | 5% | 10% | 15% | 20% |
|---|---|---|---|---|
| 10° C. | 18 KW | 24 KW | 25 KW | 25 KW |
| 25° C. | 23 KW | 46 KW | 54 KW | 62 KW |

If the state of charge of the battery at the current moment is 10%, and the state of temperature of the battery at the current moment is 25° C., it can be determined according to the corresponding relationship that the internal resistance state of the battery at the current moment is 0.615 KΩ, and the state of power of the battery at the current moment is 46 KW.

A historical open circuit voltage value of an open circuit voltage of the battery at a historical moment corresponding to a previous preset period is determined according to the sampled state of charge. The battery is sampled according to a preset period to obtain a state of charge of the battery, and according to a corresponding relationship between the state of charge of the battery and an open circuit voltage value, the historical open circuit voltage value of the open circuit voltage of the battery at the historical moment corresponding to the previous preset period can be determined, wherein the corresponding relationship between the state of charge of the battery and the open circuit voltage value is provided by a battery cell manufacturer according to batteries of different specifications.

For example, if the preset period is one second, the state of charge and the state of temperature of the battery are sampled every one second; when the sixtieth second is reached, namely, sampling is performed to obtain the state of charge and the state of temperature of the battery at the current moment during the sixtieth preset period, at this moment, the internal resistance state of the battery at the current moment and the state of power of the battery at the current moment are determined by means of the corresponding relationship among the state of charge and the state of temperature of the battery at the current moment during the sixtieth preset period and the internal resistance state at the current moment and the state of power of the battery at the current moment; and by means of the state of charge of the battery sampled in the previous preset period, namely, the sampled fifty-ninth second, that is to say, the sampled state of charge at the fifty-ninth preset period, the open circuit voltage value of the open circuit voltage of the battery during the fifty-ninth preset period, namely, the historical open circuit voltage value of the open circuit voltage of the battery at the historical moment corresponding to the previous preset period, is determined according to the corresponding relationship between the state of charge of the battery and the open circuit voltage value.

The ampere-hour value corresponding to each preset period is respectively calculated according to the state of power of each preset period, the internal resistance state of the preset period, and the historical open circuit voltage value of the open-circuit voltage of the battery at the historical moment corresponding to the previous preset period.

In one example, a current value of the battery at the current moment is determined according to the state of power, the internal resistance state, and the historical open circuit voltage value. After determining the internal resistance state at the current moment of the battery and a state of power of the battery at the current moment and a historical open circuit voltage value of the battery corresponding to the previous preset period according to sampling a state of charge and a state of temperature of the battery, an ampere-hour value corresponding to each preset period is respectively calculated according to the state of power at the current moment of the preset period, the internal resistance state at the current moment and the historical open circuit voltage value of the battery corresponding to the previous preset period. For example, in the current period, it is determined that the state of power at the current moment is Pₜ, the internal resistance state at the current moment is Rₜ, and the historical open circuit voltage value of the battery corresponding to the previous preset period is U_{ocv, t-1}, and in the present embodiment, the current value Iₜ of the battery at the current moment during the current preset period can be calculated through formula (1).

$${I}_{t} = \frac{{P}_{t}}{{U}_{o c v , t - 1} - {I}_{t} * {R}_{t}} \qquad Formula ( 1 )$$

By simplifying Formula (1), Formula (2) can be obtained:

$${R}_{t} * {I}_{t}^{2} - {U}_{ocv , t - 1} * {I}^{t} + {P}_{t} = 0 \qquad Formula ( 2 )$$

By solving Formula (2), Formula (3) can be obtained:

$${I}_{t} = \frac{{U}_{o c v , t - 1} \pm \sqrt{{U}_{o c v , t - 1}^{2} + 4 * {R}_{t}}}{2 * {R}_{t}} \qquad Formula ( 3 )$$

Since the current value of the battery is a positive value, Formula (3) is solved as Formula (4):

$${I}_{t} = \frac{{U}_{o c v , t - 1} + \sqrt{{U}_{o c v , t - 1}^{2} + 4 * {R}_{t}}}{2 * {R}_{t}} \qquad Formula ( 4 )$$

According to the current value of the battery at the current moment of each preset period, the ampere-hour value corresponding to each preset period is respectively calculated. After the current value of the battery at the current moment during the current period is calculated through the above-mentioned formula (4), the current value of the battery at the current moment in each preset period can be respectively calculated, and then the ampere-hour value corresponding to each preset period can be respectively calculated according to the current value corresponding to each preset period. In this embodiment, the ampere-hour value corresponding to the preset period can be calculated through formula (5), wherein T is a time interval of the preset period, and Ahₜ is the ampere-hour value at the current moment. For example, if the preset period is one second, then T in Formula (5) is 1S.

$$A {h}_{t} = {I}_{t *} T \qquad Formula ( 5 )$$

Step 203, accumulating the ampere-hour value corresponding to each preset period to obtain the initial reference ampere-hour integral value.

After the ampere-hour value corresponding to each preset period is respectively calculated, the ampere-hour value corresponding to each preset period is accumulated, which can be calculated through Formula (6) in this embodiment, and the calculated value is the initial reference ampere-hour integral value, wherein Ahₜₒₗ is the initial reference ampere-hour integral value.

$$A {h}_{tol} = \sum A {h}_{t} \qquad Formula ( 6 )$$

Step 102, calculating an accumulated ampere-hour discharge capacity from a moment when the state of charge of the battery starts to be lower than the preset state of charge threshold value to the current moment.

When it is detected that the state of charge of the battery reaches the preset state of charge threshold value, it is started to detect and count the ampere-hour discharge capacity of the battery, and according to the ampere-hour discharge capacity of the battery which is detected and counted, then the accumulated ampere-hour discharge capacity of the battery from the moment when the state of charge starts to be lower than the preset state of charge threshold value to the current moment is calculated. When the state of charge of the battery reaches the preset state of charge threshold value, according to a preset statistical period, the ampere-hour discharge capacity corresponding to each period is respectively counted, and then the ampere-hour discharge capacity corresponding to each period is accumulated to obtain the accumulated ampere-hour discharge capacity of the battery from the moment when the state of charge starts to be lower than the preset state of charge threshold value to the current moment.

Step 103, providing an early warning to prevent an over discharge of the battery when a value of the accumulated ampere-hour discharge capacity reaches the reference ampere-hour integral value.

When it is detected that the accumulated ampere-hour discharge capacity of the battery reaches the acquired reference ampere-hour integral value, the early warning is performed to prevent the battery from being over discharged, among them, the early warning message can be pushed in at least one of the manners including voice, text, short message, etc. When a user borrows a vehicle for a friend to use or the vehicle is not around himself, at this moment, the accumulated discharge capacity of the battery of the vehicle reaches the reference ampere-hour integral value, the user can learn early warning information by means of short message push, and at this moment, the user can prompt the friend in time or charge the battery in time, so as to avoid damage to the battery due to over discharge of the battery, and protect the battery to extend the use time of the battery.

In one example, when the value of the accumulated ampere-hour discharge capacity of the battery reaches the acquired reference ampere-hour integration value, the function consuming the battery without affecting the normal driving may be automatically turned off while the early warning for preventing the over discharge of the battery is performed, thereby reducing the over discharge of the battery and automatically protecting the battery. The functions that do not affect normal driving include an air conditioning function, a player function, a seat heating function, etc. of the vehicle, and the present disclosure is not particularly limited here.

In one example, when the value of the accumulated ampere-hour discharge capacity of the battery reaches the acquired reference ampere-hour integration value, when the early warning is performed to prevent the over discharge of the battery, if the vehicle has a backup battery at this time and the backup battery can be normally used, the battery for powering the vehicle can also be automatically switched to the backup battery at this time, so as to avoid damage to the battery due to the over discharge of the battery, while the battery can be automatically protected. For example, the vehicle carries not only one battery or a group of batteries, but also a backup battery, and the backup battery and the battery being used are present in the same system or the same circuit, when the battery being used by the vehicle for powering is switched to the backup battery, the normal use of the user is not affected. Specifically, at the time of switching, the user does not have the feeling of switching the batteries, and only knows that the batteries have been automatically switched through a switching prompt or a battery use indication, and the user's experience on using the batteries is not affected.

In the above-mentioned embodiment of the present disclosure, rather than using a set time to determine the electric quantity state of the battery, whether the battery is over discharged is determined according to the relationship between the accumulated ampere-hour discharge capacity of the battery and the pre-detected reference ampere-hour integral value. The specific discharging ampere-hour value of the battery in each preset period can be accurately known through the accumulated ampere-hour discharge capacity. Using the set time for determination, only the time period during which the battery is discharged can be determined, and the actual total ampere-hour value in the set time cannot be accurately known. Therefore, through the present disclosure, the ampere-hour value with which the battery is discharged and the ampere-hour integral value with which the battery is prevented from over discharge can be accurately and clearly known. Furthermore, the battery is not affected by the aging of the battery, and the battery is early warned in time to prevent the battery from damage due to over discharge, which effectively protects the battery.

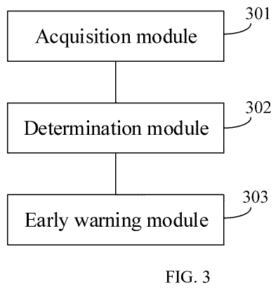

FIG. 3 is a structural block diagram of a battery early warning apparatus provided in an embodiment of the present application, which specifically includes the following modules:
an acquisition module 301 configured for acquiring a reference ampere-hour integral value 301, wherein the reference ampere-hour integral value is an ampere-hour integral value when a battery is capable to be normally used after a state of charge of a battery is lower than a preset state of charge threshold value;
a determination module 302 configured for calculating an accumulated ampere-hour discharge capacity from a moment when the state of charge of the battery starts to be lower than the preset state of charge threshold value to the current moment; and
an early warning module 303 configured for providing an early warning to prevent an over discharge of the battery when the value of the accumulated ampere-hour discharge capacity reaches the reference ampere-hour integral value.

In an embodiment of the present description, the acquisition module 301 includes:
an acquisition sub-module configured for acquiring an initial reference ampere-hour integral value; and
a first calculation sub-module configured for calculating the reference ampere-hour integral value on the basis of the initial reference ampere-hour integral value and the current state of health.

In one embodiment of the present disclosure, the apparatus further includes:
a sampling module configured for sampling the state of charge and a state of temperature of the battery according to a preset period within a preset filtering duration after the state of charge of the battery is lower than the preset state of charge threshold value;
a calculation module configured for respectively calculating an ampere-hour value corresponding to each preset period according to the sampled state of charge and the state of temperature in each preset period; and
an accumulation module configured for accumulating the ampere-hour value corresponding to each preset period to obtain the initial reference ampere-hour integral value.

In an embodiment of the present description, the calculation module includes:
a first determination sub-module configured for determining an internal resistance state of the battery at the current moment and a state of power of the battery at the current moment according to the state of charge and the state of temperature that are sampled;
a second determination sub-module configured for determining a historical open circuit voltage value of an open circuit voltage of the battery at a historical moment corresponding to a previous preset period according to the state of charge that is sampled; and
a second calculation sub-module configured for respectively calculating the ampere-hour value corresponding to each preset period according to the state of power, the internal resistance state and the historical open circuit voltage value of each preset period.

In an embodiment of the present disclosure, the second calculation sub-module includes:
a determination unit configured for determining a current value of the battery at the current moment according to the state of power, the internal resistance state, and the historical open circuit voltage value; and
calculation unit configured for respectively calculating the ampere-hour value corresponding to each preset period according to the current value of the battery at the current moment of each preset period.

In one embodiment of the present disclosure, the apparatus further includes:
an automatic shutdown module configured for automatically shutting down a function that consumes the battery without affecting normal driving.

In one embodiment of the present disclosure, the apparatus further includes:
an automatic switching module configured for automatically switching the battery used to power a vehicle to a backup battery of the vehicle, wherein the backup battery is a battery that can be normally used.

In an embodiment of the present description, the early warning module includes:
a pushing sub-module configured for, when a value of the accumulated ampere-hour discharge capacity reaches the reference ampere-hour integral value, pushing an early warning message in at least one of the manners including voice, text and short message.

In the above-mentioned embodiment of the present disclosure, rather than using a set time to determine the electric quantity state of the battery, whether the battery is over discharged is determined according to the relationship between the accumulated ampere-hour discharge capacity of the battery and the pre-detected reference ampere-hour integral value. The specific discharging ampere-hour value of the battery in each preset period can be accurately known through the accumulated ampere-hour discharge capacity. Using the set time for determination, only the time period during which the battery is discharged can be determined, and the actual total ampere-hour value in the set time cannot be accurately known. Therefore, through the present disclosure, the ampere-hour value with which the battery is discharged and the ampere-hour integral value with which the battery is prevented from over discharge can be accurately and clearly known. Furthermore, the battery is not affected by the aging of the battery, and the battery is early warned in time to prevent the battery from damage due to over discharge, which effectively protects the battery.

For the apparatus embodiments, which are substantially similar to the method embodiments, the description is relatively simple, with reference to the partial description of the method embodiments.

An embodiment of the present application also provides a vehicle, including:
a processor, a memory and a computer program stored on the memory and capable of running on the processor, wherein the computer program, when executed by the processor, implements the various processes of the above-mentioned embodiment of the battery early warning method and can achieve the same technical effect, and in order to avoid repetition, the description thereof will not be repeated.

The present disclosure further discloses a computer-readable storage medium, wherein the computer-readable storage medium stores a computer program, and the computer program, when executed by a processor, implements the various processes of the above-mentioned embodiment of the battery early warning method and can achieve the same technical effect, and in order to avoid repetition, the description thereof will not be repeated.

The various component embodiments disclosed herein can be implemented in hardware, software modules running on one or more processors, or a combination thereof. A person skilled in the art should understand that microprocessors or digital signal processors (DSPs) can be used in practice to implement some or all of the functions of some or all components in the computing and processing device according to the embodiments of the present disclosure. The present disclosure can also be implemented as a device or apparatus program (e.g., computer program and computer program product) for performing part or all of the methods described herein. Such a program implementing the present disclosure may be stored on a computer-readable medium or may be in the form of one or more signals. Such signals may be downloaded from an Internet website, provided on a carrier signal, or provided in any other form.

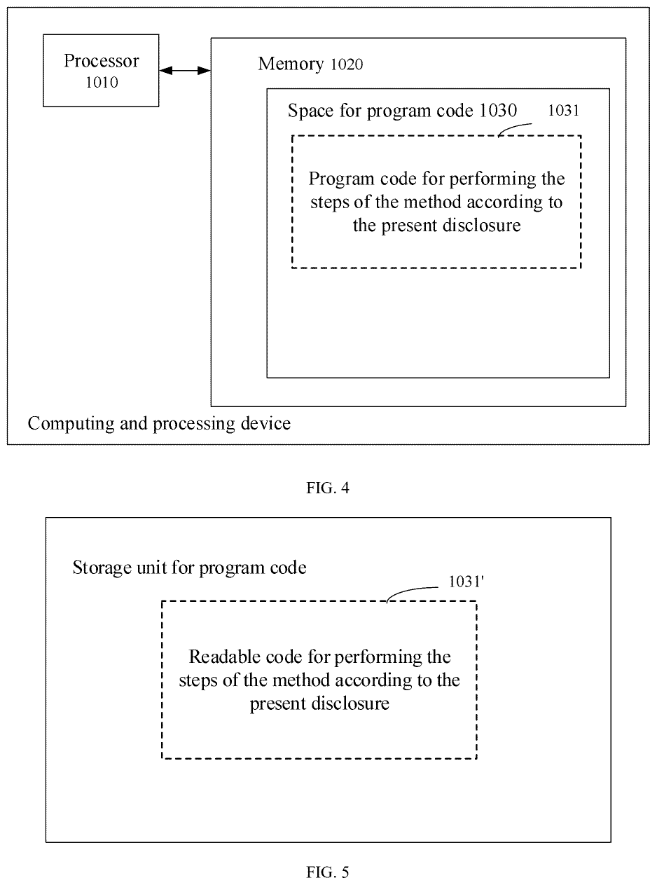

For example, FIG. 4 illustrates a computing and processing device that may implement the method in accordance with the present disclosure. The computing and processing device conventionally includes a processor 1010 and a computer program product or a computer-readable medium in the form of a memory 1020. The memory 1020 may be an electronic memory such as flash memory, EEPROM (electrically erasable programmable read only memory), EPROM, hard disk, or ROM, etc. The memory 1020 has a storage space 1030 for program code 1031 for performing any of the method steps described above. For example, the storage space 1030 for the program code may include respective program codes 1031 for implementing the various steps in the above-mentioned method, respectively. The program code may be read from or written to one or more computer program products. These computer program products include a program code carrier such as a hard disk, a compact disc (CD), a memory card or a floppy disk. Such a computer program product is typically a portable or fixed storage unit as described with reference to FIG. 5. The storage unit may have memory segments, storage space, etc. arranged similarly to the memory 1020 in the computing and processing device of FIG. 4. The program code may, for example, be compressed in a suitable form. Typically, the storage unit includes computer-readable code 1031′, i.e. code that can be read by a processor, e.g. such as 1010, which, when executed by a computing and processing device, causes the computing and processing device to perform the various steps of the method described above.

The key points of each embodiment in the present disclosure are the differences from other embodiments, and the same and similar parts among various embodiments can be referred to each other.

A person skilled in the art will appreciate that embodiments of the embodiments of the present disclosure may be provided as a method, apparatus, or computer program product. Accordingly, embodiments of the present disclosure may take the form of an entirely hardware embodiment, an entirely software embodiment or an embodiment combining software and hardware aspects. Moreover, embodiments of the present disclosure can take the form of a computer program product embodied on one or more computer-usable storage media having computer-usable program code embodied therein (including but not limited to disk storage, CD-ROM, optical storage, etc.).

The embodiments of the present disclosure are described with reference to flowchart illustrations and/or block diagrams of methods, terminal devices (systems), and computer program products according to embodiments of the present disclosure. It will be understood that each flow and/or block of the flowcharts and/or block diagrams, and combinations of flows and/or blocks in the flowcharts and/or block diagrams, can be implemented by computer program instructions. These computer program instructions may be provided to a processor of a general purpose computer, special purpose computer, embedded processor, or other programmable data processing terminal device to produce a machine, such that the instructions, which are executed via the processor of the computer or other programmable data processing terminal device, create means for implementing the functions specified in the flow or flows in the flowchart and/or block or blocks in the block diagram.

These computer program instructions may also be stored in a computer-readable memory that can direct a computer or other programmable data processing terminal device to function in a particular manner, such that the instructions stored in the computer-readable memory produce an article of manufacture including instruction apparatus which implements the function specified in the one process flowchart flow or flows and/or block diagram block or blocks.

These computer program instructions may also be loaded onto a computer or other programmable data processing terminal device to cause a series of operational steps to be performed on the computer or other programmable terminal device to produce a computer implemented process such that the instructions which execute on the computer or other programmable terminal device provide steps for implementing the functions specified in the flow or flows in the flowchart and/or the block or blocks in the block diagram.

While preferred embodiments of the embodiments of the present disclosure have been described, additional variations and modifications to these embodiments will occur to a person skilled in the art once the basic inventive concept is known. Therefore, it is intended that the appended claims be interpreted as including the preferred embodiments and all variations and modifications that fall within the scope of the embodiments of the present disclosure.

Finally, it is noted that relational terms such as first and second, and the like, may be used herein merely to distinguish one entity or action from another entity or action without necessarily requiring or implying any actual such relationship or order between such entities or actions. Furthermore, the terms “include”, “comprise”, or any other variation thereof, are intended to cover a non-exclusive inclusion, such that a process, method, article, or terminal device that includes a list of elements not only includes those elements but may include other elements not expressly listed or inherent to such process, method, article, or terminal device. An element proceeded by the phrase “comprise a” does not, without more constraints, preclude the existence of additional identical elements in the process, method, article, or terminal device that comprises the element.

A battery early warning method and a battery early warning apparatus provided in the present disclosure are described in detail above, and the principles and implementations of the present disclosure are described herein using specific examples. The description of the above-mentioned embodiments is merely used for helping to understand the method and the core idea of the present disclosure. At the same time, for a person skilled in the art, according to the idea of the present disclosure, there would be changes in the specific implementations and the application scope, and in summary, the contents of the present description should not be construed as limiting the present disclosure.

What is claimed is:

1. A battery early warning method, comprising:
acquiring a reference ampere-hour integral value, wherein the reference ampere-hour integral value is an ampere-hour integral value when a battery is allowed to be normally used after a state of charge of the battery is lower than a preset state of charge threshold value;
calculating an accumulated ampere-hour discharge capacity from a moment when the state of charge of the battery starts to be lower than the preset state of charge threshold value to a current moment; and
providing an early warning to prevent an over discharge of the battery when a value of the accumulated ampere-hour discharge capacity reaches the reference ampere-hour integral value.

2. The battery early warning method according to claim 1, wherein a step of acquiring the reference ampere-hour integral value comprises:
acquiring an initial reference ampere-hour integral value and a current state of health of the battery; and
calculating the reference ampere-hour integral value on the basis of the initial reference ampere-hour integral value and the current state of health.

3. The battery early warning method according to claim 2, wherein the initial reference ampere-hour integral value is determined through following steps:
sampling the state of charge and a state of temperature of the battery according to a preset period within a preset filtering duration after the state of charge of the battery is lower than the preset state of charge threshold value;
respectively calculating an ampere-hour value corresponding to each preset period according to the state of charge and the state of temperature sampled in each preset period; and
accumulating the ampere-hour value corresponding to each preset period to obtain the initial reference ampere-hour integral value.

4. The battery early warning method according to claim 3, wherein a step of respectively calculating the ampere-hour value corresponding to each preset period according to the state of charge and the state of temperature sampled in each preset period comprises:
determining an internal resistance state of the battery at the current moment and a state of power of the battery at the current moment according to the state of charge and the state of temperature that are sampled;
determining a historical open circuit voltage value of an open circuit voltage of the battery at a historical moment corresponding to a previous preset period according to the state of charge sampled; and
respectively calculating the ampere-hour value corresponding to each preset period according to the state of power, the internal resistance state and the historical open circuit voltage value of each preset period.

5. The battery early warning method according to claim 1, wherein after a step of providing the early warning to prevent the over discharge of the battery when the value of the accumulated ampere-hour discharge capacity reaches the reference ampere-hour integral value, the battery early warning method further comprises:
automatically shutting down a function that consumes the battery without affecting normal driving.

6. The battery early warning method according to claim 1, wherein after a step of providing the early warning to prevent the over discharge of the battery when the value of the accumulated ampere-hour discharge capacity reaches the reference ampere-hour integral value, the battery early warning method further comprises:
automatically switching the battery configured to power a vehicle to a backup battery of the vehicle, wherein the backup battery is a battery allowed to be normally used.

7. The battery early warning method according to claim 1, wherein a step of providing the early warning to prevent the over discharge of the battery when the value of the accumulated ampere-hour discharge capacity reaches the reference ampere-hour integral value comprises:
when the value of the accumulated ampere-hour discharge capacity reaches the reference ampere-hour integral value, pushing an early warning message in at least one of manners comprising voice, text and short message.

8. (canceled)

9. A vehicle, comprising: a processor, a memory, and a computer program stored on the memory and allowed for running on the processor, wherein the computer program, when executed by the processor, implements steps of the battery early warning method according to claim 1.

10. A non-transitory computer-readable storage medium, wherein the non-transitory computer-readable storage medium stores a computer program thereon, and the computer program, when executed by a processor, implements steps of the battery early warning method according to claim 1.

11. A computing and processing device, comprising:
a memory where a computer-readable code is stored; and
at least one processor, wherein when the computer-readable code is executed by the at least one processor, the computing and processing device performs the battery early warning method according to claim 1.

12. (canceled)

13. The vehicle according to claim 9, wherein in the battery early warning method, a step of acquiring the reference ampere-hour integral value comprises:
acquiring an initial reference ampere-hour integral value and a current state of health of the battery; and
calculating the reference ampere-hour integral value on the basis of the initial reference ampere-hour integral value and the current state of health.

14. The vehicle according to claim 13, wherein in the battery early warning method, the initial reference ampere-hour integral value is determined through following steps:
sampling the state of charge and a state of temperature of the battery according to a preset period within a preset filtering duration after the state of charge of the battery is lower than the preset state of charge threshold value;
respectively calculating an ampere-hour value corresponding to each preset period according to the state of charge and the state of temperature sampled in each preset period; and
accumulating the ampere-hour value corresponding to each preset period to obtain the initial reference ampere-hour integral value.

15. The vehicle according to claim 14, wherein in the battery early warning method, a step of respectively calculating the ampere-hour value corresponding to each preset period according to the state of charge and the state of temperature sampled in each preset period comprises:
determining an internal resistance state of the battery at the current moment and a state of power of the battery at the current moment according to the state of charge and the state of temperature that are sampled;
determining a historical open circuit voltage value of an open circuit voltage of the battery at a historical moment corresponding to a previous preset period according to the state of charge sampled; and
respectively calculating the ampere-hour value corresponding to each preset period according to the state of power, the internal resistance state and the historical open circuit voltage value of each preset period.

16. The vehicle according to claim 9, wherein in the battery early warning method, after a step of providing the early warning to prevent the over discharge of the battery when the value of the accumulated ampere-hour discharge capacity reaches the reference ampere-hour integral value, the battery early warning method further comprises:
automatically shutting down a function that consumes the battery without affecting normal driving.

17. The vehicle according to claim 9, wherein in the battery early warning method, after a step of providing the early warning to prevent the over discharge of the battery when the value of the accumulated ampere-hour discharge capacity reaches the reference ampere-hour integral value, the battery early warning method further comprises:
automatically switching the battery configured to power a vehicle to a backup battery of the vehicle, wherein the backup battery is a battery allowed to be normally used.

18. The vehicle according to claim 9, wherein in the battery early warning method, a step of providing the early warning to prevent the over discharge of the battery when the value of the accumulated ampere-hour discharge capacity reaches the reference ampere-hour integral value comprises:
when the value of the accumulated ampere-hour discharge capacity reaches the reference ampere-hour integral value, pushing an early warning message in at least one of manners comprising voice, text and short message.
